(19) United States
(12) Patent Application Publication
(10) Pub. No.: US 2023/0315964 A1
(43) Pub. Date: Oct. 5, 2023

(54) DESIGN AWARE ADAPTIVE MIXED-SIGNAL SIMULATION

(71) Applicant: Siemens Industry Software Inc., Plano, TX (US)

(72) Inventors: Abhijeet Kolpekwar, Round Rock, TX (US); Kingshuk Banerjee, Austin, TX (US)

(73) Assignee: Siemens Industry Software Inc., Plano, TX (US)

(21) Appl. No.: 18/041,899

(22) PCT Filed: Aug. 25, 2020
(86) PCT No.: PCT/US2020/047824

§ 371 Date: Feb. 16, 2023

(51) Int. Cl. G06F 30/38; G06F 30/3308; G06F 30/367

(52) U.S. Cl. CPC G06F 30/38; G06F 30/3308; G06F 30/367

(57) ABSTRACT

A computing system implementing a design verification system can classify a mixed-signal circuit design describing an electronic device based on a design topology of the mixed-signal circuit design. This classification can be performed by identifying a top-level design block in the mixed-signal circuit design, traversing a connectivity of a design hierarchy to identify lower-level design blocks in the mixed-signal circuit design, and classifying the mixed-signal circuit design based on at least one of a design type of the top-level design block, design types of the lower-level design blocks, or a connectivity of design blocks in the mixed-signal circuit design. The design verification system can selectively partition the mixed-signal circuit design into an analog partition and a digital partition based on the classification, and simulate the analog partition of the mixed-signal circuit design with an analog simulator and the digital partition of the mixed-signal circuit design with a digital simulator.

### TECHNICAL FIELD

This application is generally related to electronic design automation and, more specifically, to design aware adaptive mixed-signal simulation.

### BACKGROUND

Designing and fabricating electronic systems typically involves many steps, known as a “design flow.” The particular steps of a design flow often are dependent upon the type of electronic system to be manufactured, its complexity, the design team, and the fabricator or foundry that will manufacture the electronic system from a design.

Initially, a specification for a new electronic system can be transformed into a logical design. When the electronic system includes a combination of digital circuitry and analog circuitry, such as with System-On-a-Chip (SOC) devices or the like, the logical design can be a mixed-signal design describing the electronic system in terms of both the exchange of analog and digital signals between circuit components and the operations that can be performed on those signals. These mixed-signal designs are typically written in one or more Hardware Design Languages (HDLs), such as System Verilog, Very high speed integrated circuit Hardware Design Language (VHDL), Verilog Analog Mixed Signal (Verilog-AMS), VHDL-AMS, System-C, Simulation Program with Integrated Circuit Emphasis (SPICE), Eldo-SPICE, Spectre, or the like.

After the logical design has been generated, verification tools can be utilized to verify a functionality of the logical design, for example, by running simulators and/or hardware emulators, or by utilizing formal techniques, allowing any errors in the design discovered during the verification process to be corrected. Simulators of mixed-signal designs can include both an analog simulator to simulate analog portions of the mixed-signal designs, for example, using a continuous time matrix-based differential equation solver, and a digital simulator to simulate the digital portions of the mixed-signal designs, for example, using an event-based discrete time events processor.

To perform mixed-signal simulation, the simulators partition the mixed-signal design into analog portions and digital portions, and then insert translator cells to enable the simulators to manage inter-solver dependencies between an analog simulation and a digital simulation. The performance and accuracy of mixed-signal simulation directly depends on the number of translator cells inserted by the simulators. Traditional approaches to mixed-signal design partitioning identify where to partition the mixed-signal design by processing signal connectivity in the mixed-signal design. While this partitioning approach allows the simulator a standard and predictable technique to partition the mixed-signal design, it often creates additional digital-analog crossings and thus an excessive number of translator cells that can hamper simulator performance.

### SUMMARY

This application discloses a computing system implementing a design verification system to classify a mixed-signal circuit design describing an electronic device having analog circuitry and digital circuitry based on a design topology of the mixed-signal circuit design. This classification of the mixed-signal circuit can be performed by identifying a top-level design block in a design hierarchy of the mixed-signal circuit design, traversing the design hierarchy of the mixed-signal circuit design to identify lower-level design blocks in the mixed-signal circuit design, and then classifying the mixed-signal circuit design based, at least in part, on at least one of a design type of the top-level design block, design types of the lower-level design blocks, or a connectivity of design blocks in the mixed-signal circuit design.

The design verification system can selectively partition the mixed-signal circuit design into an analog partition and a digital partition based, at least in part, on the classification of the mixed-signal circuit design. When the classification of the mixed-signal circuit design corresponds to an analog-on-top topology, a digital-on-top topology, or an analog mixed-signal topology, the design verification system can partition the mixed-signal circuit design at a design block level. When the classification of the mixed-signal circuit design corresponds to complex design topology, the design verification system can partition the mixed-signal circuit design by processing the signals in the mixed-signal circuit design.

The design verification system can locate transitions between types of design blocks in the mixed-signal circuit design and insert one or more boundary design blocks into the analog partition or the digital partition of the mixed-signal circuit design at the transitions between the types of the design blocks based, at least in part, on the classification of the topology of the mixed-signal circuit design. The design verification system also can insert translator cells into the mixed-signal circuit design between the analog partition and the digital partition.

The design verification system can elaborate the analog partition, the digital partition, and the translator cells, and then simulate the analog partition of the mixed-signal circuit design with an analog simulator and the digital partition of the mixed-signal circuit design with a digital simulator. The analog simulator and the digital simulator can communicate during their simulations via the translator cells. Embodiments of will be described below in greater detail.

### DESCRIPTION OF THE DRAWINGS

FIGS. 1 and 2 illustrate an example of a computer system of the type that may be used to implement various embodiments.

FIG. 3 illustrates an example design verification system for performing design aware adaptive mixed-signal simulation that may be implemented according to various embodiments.

FIG. 4 illustrates a flowchart showing an example implementation of design aware adaptive mixed-signal simulation according to various examples.

FIGS. 5A and 5B illustrates an example of design aware partitioning of a mixed signal circuit design with an analog on top design topology according to various embodiments.

FIGS. 6A and 6B illustrates example of design aware partitioning of a mixed signal circuit design with a digital on top design topology according to various embodiments.

FIGS. 7A and 7B illustrates example of design aware partitioning of a mixed signal circuit design with a Verilog AMS design block included in design topology according to various embodiments.

### DETAILED DESCRIPTION

### Illustrative Operating Environment

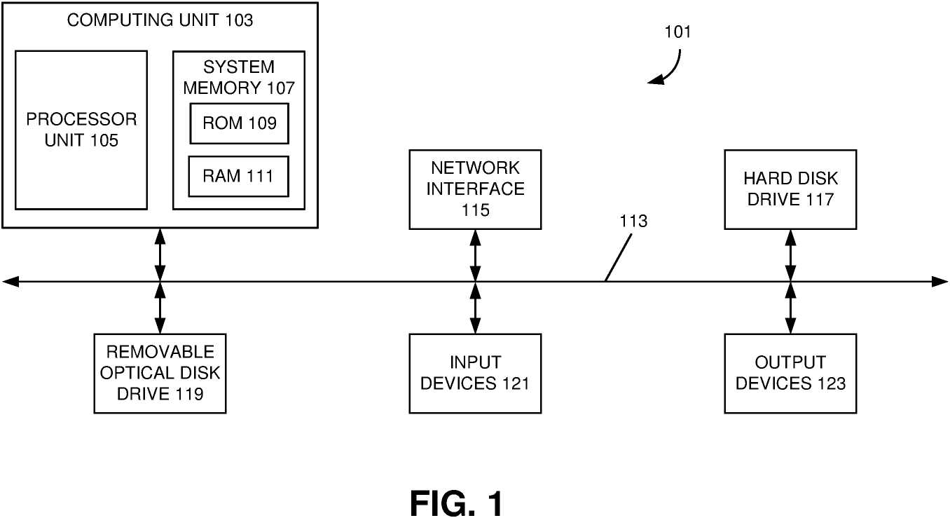

Various examples may be implemented through the execution of software instructions by a computing device 101, such as a programmable computer. Accordingly, FIG. 1 shows an illustrative example of a computing device 101. As seen in this figure, the computing device 101 includes a computing unit 103 with a processor unit 105 and a system memory 107. The processor unit 105 may be any type of programmable electronic device for executing software instructions, but will conventionally be a microprocessor. The system memory 107 may include both a read-only memory (ROM) 109 and a random access memory (RAM) 111. As will be appreciated by those of ordinary skill in the art, both the read-only memory (ROM) 109 and the random access memory (RAM) 111 may store software instructions for execution by the processor unit 105.

The processor unit 105 and the system memory 107 are connected, either directly or indirectly, through a bus 113 or alternate communication structure, to one or more peripheral devices 115-123. For example, the processor unit 105 or the system memory 107 may be directly or indirectly connected to one or more additional memory storage devices, such as a hard disk drive 117, which can be magnetic and/or removable, a removable optical disk drive 119, and/or a flash memory card. The processor unit 105 and the system memory 107 also may be directly or indirectly connected to one or more input devices 121 and one or more output devices 123. The input devices 121 may include, for example, a keyboard, a pointing device (such as a mouse, touchpad, stylus, trackball, or joystick), a scanner, a camera, and a microphone. The output devices 123 may include, for example, a monitor display, a printer and speakers. With various examples of the computing device 101, one or more of the peripheral devices 115-123 may be internally housed with the computing unit 103. Alternately, one or more of the peripheral devices 115-123 may be external to the housing for the computing unit 103 and connected to the bus 113 through, for example, a Universal Serial Bus (USB) connection.

With some implementations, the computing unit 103 may be directly or indirectly connected to a network interface 115 for communicating with other devices making up a network. The network interface 115 can translate data and control signals from the computing unit 103 into network messages according to one or more communication protocols, such as the transmission control protocol (TCP) and the Internet protocol (IP). Also, the network interface 115 may employ any suitable connection agent (or combination of agents) for connecting to a network, including, for example, a wireless transceiver, a modem, or an Ethernet connection. Such network interfaces and protocols are well known in the art, and thus will not be discussed here in more detail.

It should be appreciated that the computing device 101 is illustrated as an example only, and it not intended to be limiting. Various embodiments may be implemented using one or more computing devices that include the components of the computing device 101 illustrated in FIG. 1, which include only a subset of the components illustrated in FIG. 1, or which include an alternate combination of components, including components that are not shown in FIG. 1. For example, various embodiments may be implemented using a multi-processor computer, a plurality of single and/or multiprocessor computers arranged into a network, or some combination of both.

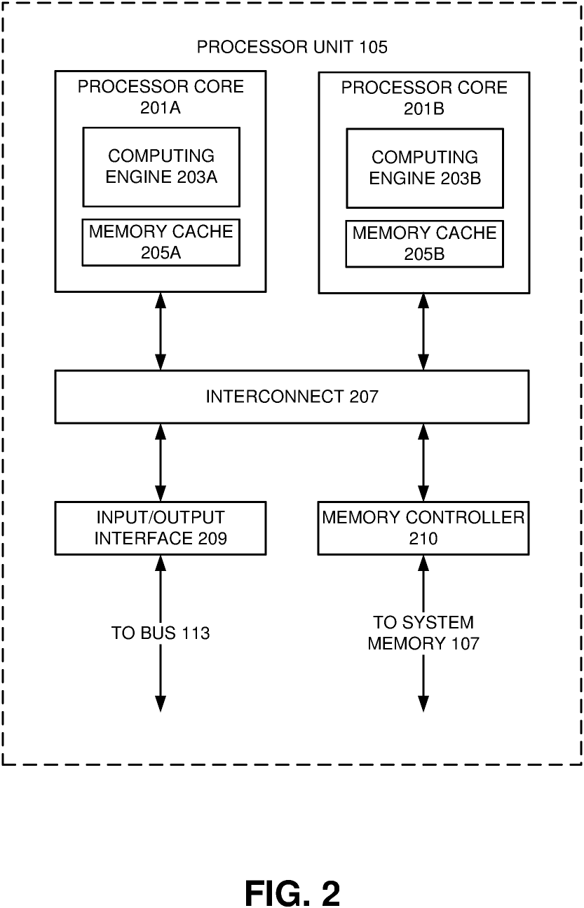

With some implementations, the processor unit 105 can have more than one processor core. Accordingly, FIG. 2 illustrates an example of a multi-core processor unit 105 that may be employed with various embodiments. As seen in this figure, the processor unit 105 includes a plurality of processor cores 201A and 201B. Each processor core 201A and 201B includes a computing engine 203A and 203B, respectively, and a memory cache 205A and 205B, respectively. As known to those of ordinary skill in the art, a computing engine 203A and 203B can include logic devices for performing various computing functions, such as fetching software instructions and then performing the actions specified in the fetched instructions. These actions may include, for example, adding, subtracting, multiplying, and comparing numbers, performing logical operations such as AND, OR, NOR and XOR, and retrieving data. Each computing engine 203A and 203B may then use its corresponding memory cache 205A and 205B, respectively, to quickly store and retrieve data and/or instructions for execution.

Each processor core 201A and 201B is connected to an interconnect 207. The particular construction of the interconnect 207 may vary depending upon the architecture of the processor unit 105. With some processor cores 201A and 201B, such as the Cell microprocessor created by Sony Corporation, Toshiba Corporation and IBM Corporation, the interconnect 207 may be implemented as an interconnect bus. With other processor units 201A and 201B, however, such as the Opteron™ and Athlon™ dual-core processors available from Advanced Micro Devices of Sunnyvale, California, the interconnect 207 may be implemented as a system request interface device. In any case, the processor cores 201A and 201B communicate through the interconnect 207 with an input/output interface 209 and a memory controller 210. The input/output interface 209 provides a communication interface to the bus 113. Similarly, the memory controller 210 controls the exchange of information to the system memory 107. With some implementations, the processor unit 105 may include additional components, such as a high-level cache memory accessible shared by the processor cores 201A and 201B. It also should be appreciated that the description of the computer network illustrated in FIG. 1 and FIG. 2 is provided as an example only, and is not intended to suggest any limitation as to the scope of use or functionality of alternate embodiments.

### Design Aware Adaptive Mixed-Signal Simulation

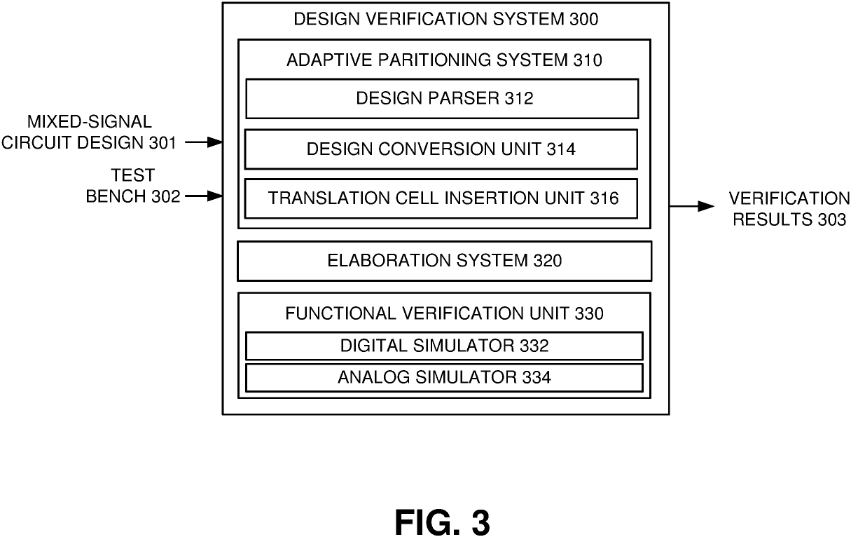

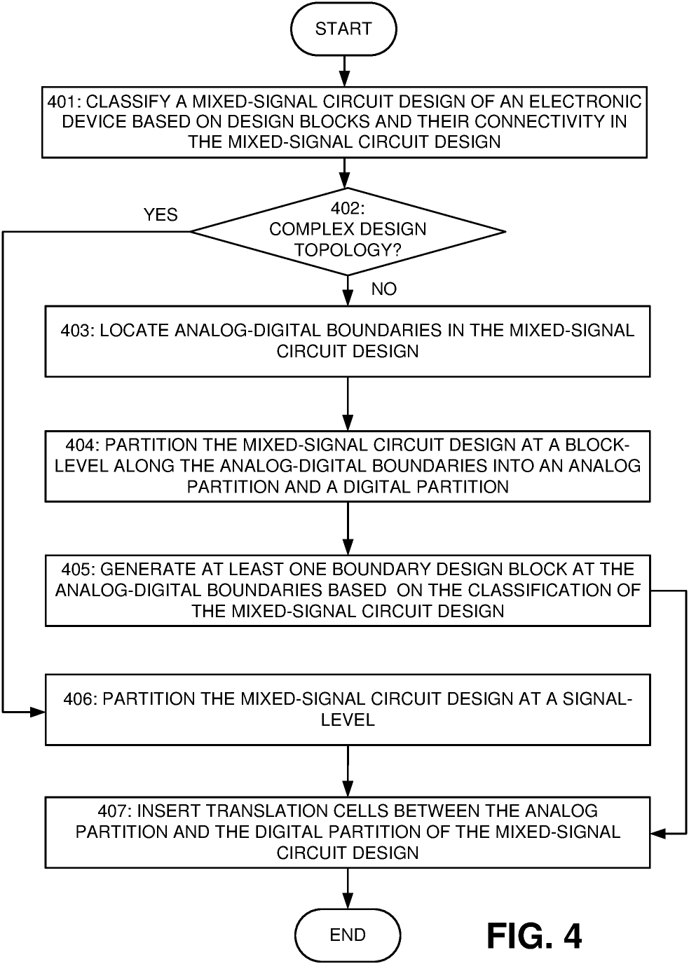

FIG. 3 illustrates an example design verification system 300 for performing design aware adaptive mixed-signal simulation that may be implemented according to various embodiments. FIG. 4 illustrates a flowchart showing an example implementation of design aware adaptive mixed-signal simulation according to various examples. Referring to FIGS. 3 and 4, the design verification system 300 can receive a mixed-signal circuit design 301 of an electronic system having both analog circuitry and digital circuitry. The mixed-signal circuit design 301 can describe the electronic system in terms of both the exchange of analog and digital signals between circuit components and the operations that can be performed on those signals. The mixed-signal circuit design 301 can be written in one or more Hardware Design Languages (HDLs), such as System Verilog, Very high speed integrated circuit Hardware Design Language (VHDL), Verilog Analog Mixed Signal (Verilog-AMS), VHDL-AMS, System-C, Simulation Program with Integrated Circuit Emphasis (SPICE), Eldo-SPICE, Spectre, or the like.

The design verification system 300, for example, implemented in the computing device 101 of FIG. 1, can receive a test bench 302 capable of defining test stimulus, for example, clock signals, activation signals, power signals, control signals, data signals, or the like, that, when grouped, may form test bench transactions capable of prompting operation of the mixed-signal circuit design 301 in a verification environment, such as a mixed-signal simulation environment. In some embodiments, the test bench 302 can be written in an object-oriented programming language, for example, SystemVerilog or the like, that, when executed during elaboration, can dynamically generate test bench components for verification of the mixed-signal circuit design 301. A methodology library, for example, a Universal Verification Methodology (UVM) library, an Open Verification Methodology (OVM) library, an Advanced Verification Methodology (AVM) library, a Verification Methodology Manual (VMM) library, or the like, can be utilized as a base for creating the test bench 302.

The design verification tool 300 can include an adaptive partitioning system 310 to partition the mixed-signal circuit design 301 into an analog partition and a digital partition based on design characteristics of the mixed-signal circuit design 301. By analyzing a block level design topology for the mixed-signal circuit design 301, rather than at the signal-level, the adaptive partitioning system 310 can selectively partition the mixed-signal circuit design 301 to preserve design blocks and reduce translation cell insertion.

The adaptive partitioning system 310 can include a design parser 312 that, in a block 401 of FIG. 4, classifies the mixed-signal circuit design 301 based, at least in part, on the design blocks and their connectivity in the mixed-signal circuit design 301. The mixed-signal circuit design 301 can have a hierarchical structure, for example, with a top-level design block connected in a tree-like format to other design blocks in the mixed-signal circuit design 301. The design parser 312 can determine whether the top-level design block in the design hierarchy corresponds to a description of analog circuitry, digital circuitry, or a combination thereof. In some embodiments, the design parser 312 can identify the type of top-level design block in the mixed-signal circuit design 301 based on the hardware description language used to write the top-level design block. The design parser 312 also can identify the type of top-level design block in the mixed-signal circuit design 301 by providing the mixed-signal circuit design 301 or the top-level design block to a digital simulator 332 or an analog simulator 334 in the design verification system 300 and ascertaining whether the digital simulator 332 or the analog simulator 334 can identify the top-level design block.

The design parser 312 can traverse the design hierarchy of mixed-signal circuit design 301 to locate other design blocks and to determine their type, such as an analog design block, a digital design block, or an analog mixed-signal design block. For example, the design parser 312 can identify connections from the top-level design block to lower-level design blocks in the mixed-signal circuit design 301 and determine a design type for the lower-level design blocks, such as an analog design block, a digital design block, or an analog mixed-signal design block. The design parser 312 can then identify connections from the lower-level design blocks to even lower-level design blocks in the mixed-signal circuit design 301 and determine a design type for the even lower-level design blocks, such as an analog design block, a digital design block, or an analog mixed-signal design block.

In some embodiments, during the traversal, the design parser 312 can identify hierarchical connectivity in the mixed-signal circuit design 301. The hierarchical connectivity can correspond to one or more signal connections between an analog design block and a digital design block that are located in different levels and branches of the design hierarchy for the mixed-signal circuit design 301. For example, when a digital design block in a lower level of a design hierarchy connects with an analog design block in a different branch of the design hierarchy, the design parser 312 can categorize the connectivity between the digital design block and the analog design block as hierarchical connectivity.

The design parser 312 can classify the mixed-signal circuit design 301 based on the type of the top-level design block of the mixed-signal circuit design 301, the design blocks located at the boundaries between the digital portion and the analog portion of the mixed-signal circuit design 301, and a presence of any hierarchical connectivity. In some embodiments, the design parser 312 can classify the mixed-signal circuit design 301 as an analog-on-top design, a digital-on-top design, a mixed-signal design that includes a Verilog AMS (Analog Mixed Signal) design block, or complex design type, such as a mixed-signal design that includes a VHDL AMS design block, an analog block connected to a digital block through a hierarchical reference, analog and digital blocks intermixed in a complex fashion, or the like.

When, in a block 402 of FIG. 4, the traversal reveals the mixed-signal circuit design 301 has a complex design type, the adaptive partitioning system 310, in a block 407 of FIG. 4, can partition the mixed-signal circuit design 301 at a signal-level, for example, by processing signal connectivity in the mixed-signal circuit design 301 and partitioning the mixed-signal circuit design 301 using a standardized algorithm described in Verilog-AMS Language Reference Manual (LRM).

When, in the block 402 of FIG. 4, the traversal reveals the mixed-signal circuit design 301 has a classification other than the complex design type, the design parser 312, in a block 403 of FIG. 4, can utilize the traversal of the design hierarchy to locate analog-digital boundaries in the mixed-signal circuit design 301. The design parser 312 can utilize the identified connections between the design blocks to discover transitions in design types for the design blocks in the design hierarchy, and associate the transitions in design type to analog-digital boundaries in the mixed-signal circuit design 301. For example, when the mixed-signal circuit design 301 has been classified as an analog-on-top design, the design parser 312 can traverse the design hierarchy of the mixed-signal circuit design 301 to identify locations where the mixed-signal circuit design 301 includes an analog design block connecting to a digital design block or an analog mixed-signal design block. Those identified locations can correspond to the analog-digital boundaries between a digital portion of the mixed-signal circuit design 301 and an analog portion of the mixed-signal circuit design 301.

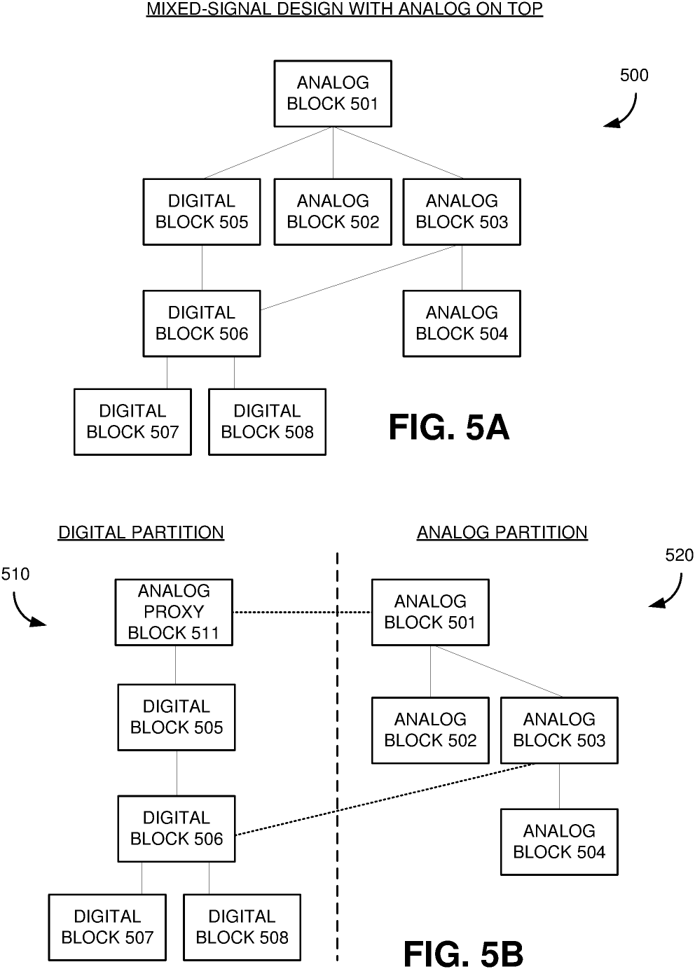

The adaptive partitioning system 310 can include a design conversion unit 314 that, in a block 404 of FIG. 4, can partition the mixed-signal circuit design 301 at a block-level along the analog-digital boundaries to create an analog partition and a digital partition, and, in a block 405 of FIG. 4, can generate at least one boundary design block for inclusion in the digital partition or the analog partition of the mixed-signal design 301. In some embodiments, the design conversion unit 314 can utilize the classification for the mixed-signal circuit design 301 to determine which design blocks to generate and where to locate the generated design blocks in the digital or analog portions of the mixed-signal circuit design 301. Embodiments of partitioning mixed-signal circuit design with different design topologies will be described below in greater detail with reference to FIGS. 5A, 5B, 6A, 6B, 7A, and 7B.

FIGS. 5A and 5B illustrates an example of design aware partitioning of a mixed signal circuit design 500 with an analog on top design topology according to various embodiments. Referring to FIG. 5A, the mixed signal circuit design 500 can describe an electronic device as a plurality of analog blocks 501-504 describing analog circuitry and a plurality of digital blocks 505-508 describing digital circuitry. The mixed signal circuit design 500 can arrange the analog blocks 501-504 and the digital blocks 505-508 hierarchically, for example, in a tree-like design hierarchy, and describe the connectivity between the analog blocks 501-504 and the digital blocks 505-508.

During design aware partitioning of the mixed signal circuit design 500, a design verification system can determine that the mixed signal circuit design 500 has an analog on top design topology due to the presence of the analog block 501 located at the top of the design hierarchy and an absence of other complex design blocks, such as analog mixed signal design block describing both analog and digital circuitry, or complex connectivity, such as hierarchical connectivity between lower-level analog and digital blocks.

Referring to FIG. 5B, the design verification system can leverage the analog on top design topology of the mixed signal circuit design 500 to generate a digital partition 510 and an analog partition 520 of the mixed signal circuit design 500. The digital partition 510 can include an analog proxy block 511 and the digital blocks 505-508. The analog proxy block 511 can be a digital block that acts as a proxy for the analog block 501 on top on the design hierarchy for the mixed signal circuit design 500. The analog partition 520 can include the analog blocks 501-504 arranged with the same hierarchy as the mixed signal circuit design 500. The digital partition 510 and the analog partition 520 can retain the same connectivity between the digital blocks 505-508 and the analog blocks 501-504, except the original connectivity between the analog block 501 and the digital block 505 can be routed through the analog proxy block 511.

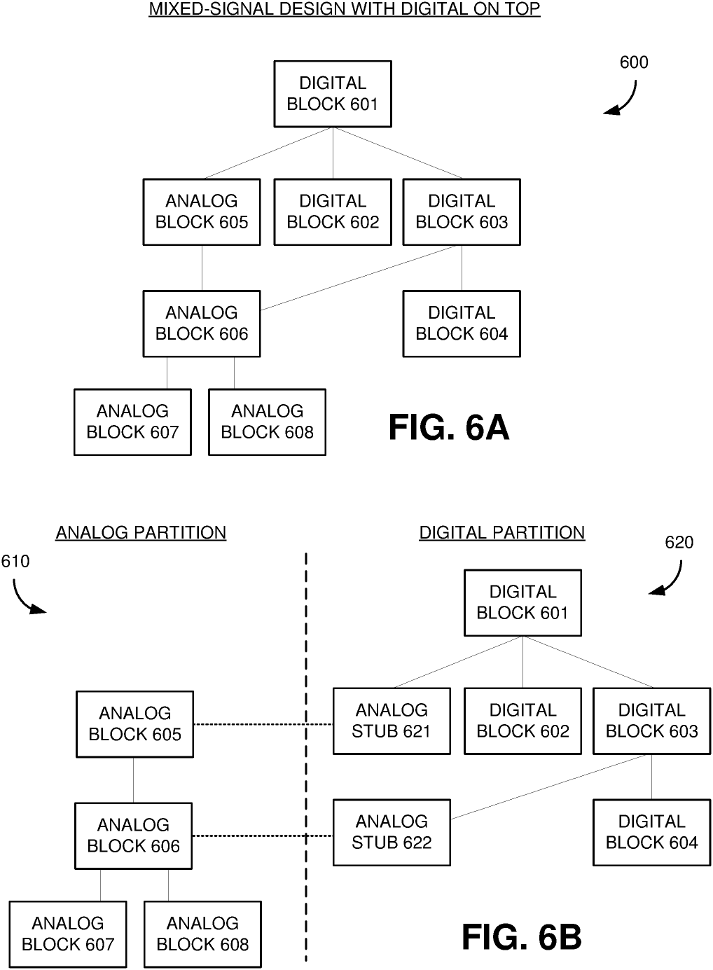

FIGS. 6A and 6B illustrates example of design aware partitioning of a mixed signal circuit design 600 with a digital on top design topology according to various embodiments. Referring to FIG. 6A, the mixed signal circuit design 600 can describe an electronic device as a plurality of digital blocks 601-604 describing digital circuitry and a plurality of analog blocks 605-608 describing analog circuitry. The mixed signal circuit design 600 can arrange the digital blocks 601-604 and the analog blocks 605-608 hierarchically, for example, in a tree-like design hierarchy, and describe the connectivity between the digital blocks 601-604 and the analog blocks 605-608.

During design aware partitioning of the mixed signal circuit design 600, a design verification system can determine that the mixed signal circuit design 600 has a digital on top design topology due to the presence of the digital block 601 located at the top of the design hierarchy and an absence of other complex design blocks, such as analog mixed signal design block describing both analog and digital circuitry, or complex connectivity, such as hierarchical connectivity between lower-level analog and digital blocks.

Referring to FIG. 6B, the design verification system can leverage the digital on top design topology of the mixed signal circuit design 600 to generate an analog partition 610 and a digital partition 620 of the mixed signal circuit design 600. The analog partition 610 can include the analog blocks 605-608 arranged with the same hierarchy as the mixed signal circuit design 600. The digital partition 620 can include the digital blocks 601-604 arranged with the same hierarchy as the mixed signal circuit design 600 along with analog stub blocks 621 and 622. The analog stub blocks 621 and 622 can be digital blocks capable of facilitating communication to the analog blocks 605 and 606, respectively, in the analog partition 610 during simulation. The analog partition 610 and the digital partition 620 can retain the same connectivity between the analog blocks 605-608 and the digital blocks 601-604, except the original connectivity between the analog blocks 605 and 606 and the digital blocks 601 and 603 can be routed through the analog stub blocks 621 and 622, respectively.

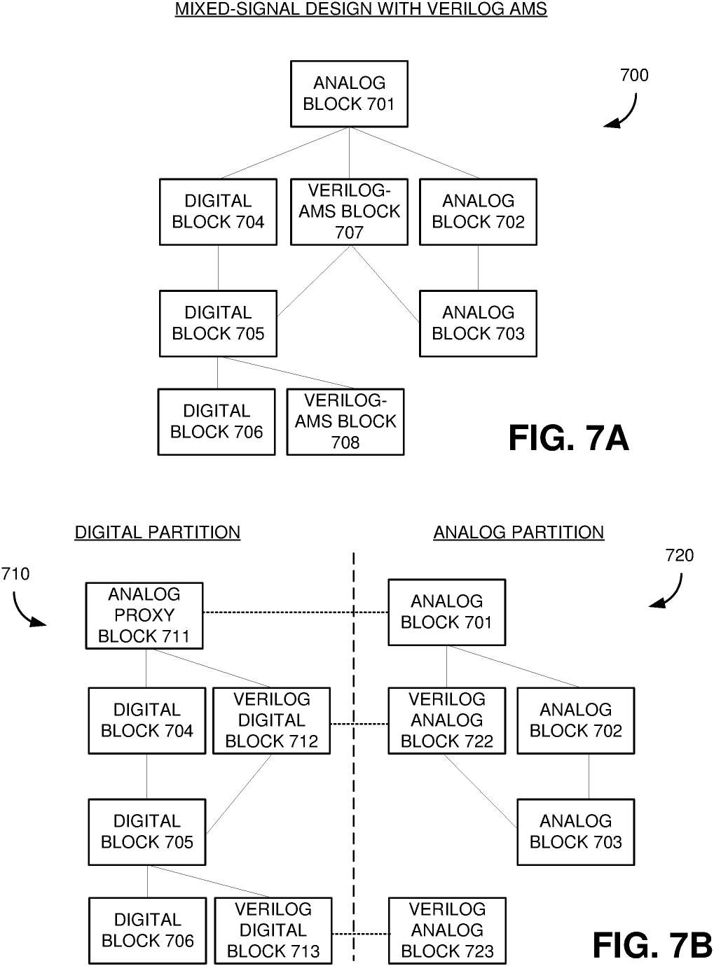

FIGS. 7A and 7B illustrates example of design aware partitioning of a mixed signal circuit design 700 with a Verilog AMS design block included in design topology according to various embodiments. Referring to FIG. 7A, the mixed signal circuit design 700 can describe an electronic device as a plurality of analog blocks 701-703 describing analog circuitry, a plurality of digital blocks 704-706 describing digital circuitry, and a plurality of Verilog-AMS blocks 707 and 708 describing both analog and digital circuitry in a Verilog AMS language. The mixed signal circuit design 700 can arrange the analog blocks 701-703, the digital blocks 704-706, and the Verilog-AMS blocks 707 and 708 hierarchically, for example, in a tree-like design hierarchy, and describe the connectivity between the analog blocks 701-703, the digital blocks 704-706, and the Verilog-AMS blocks 707 and 708.

During design aware partitioning of the mixed signal circuit design 700, a design verification system can determine that the mixed signal circuit design 700 has an analog mixed signal design topology due to the presence of the Verilog-AMS blocks 707 and 708 and an absence of other complex design blocks, such as VHDL analog mixed signal (VHDL-AMS) design block describing both analog and digital circuitry, or complex connectivity, such as hierarchical connectivity between lower-level analog and digital blocks.

Referring to FIG. 7B, the design verification system can leverage the analog on top design topology of the mixed signal circuit design 700 to generate a digital partition 710 and an analog partition 720 of the mixed signal circuit design 700. The digital partition 710 can include an analog proxy block 711, the digital blocks 704-706, and Verilog digital blocks 712 and 713. The analog proxy block 711 can be a digital block that acts as a proxy for the analog block 701 on top on the design hierarchy for the mixed signal circuit design 700. The Verilog digital blocks 712 and 713 can be digital blocks corresponding to the digital portions of the Verilog-AMS blocks 707 and 708, respectively, in the mixed signal circuit design 700. The analog partition 720 can include the analog blocks 701-703 arranged with the same hierarchy as the mixed signal circuit design 700, and include Verilog analog blocks 722 and 723. The Verilog analog blocks 722 and 723 can be analog blocks corresponding to the analog portions of the Verilog-AMS blocks 707 and 708, respectively, in the mixed signal circuit design 700.

The digital partition 710 and the analog partition 720 can retain the same connectivity between the digital blocks 704-706 and the analog blocks 701-703, except the original connectivity between the analog block 701 and the digital block 704 can be routed through the analog proxy block 711. Since the Verilog-AMS blocks 707 and 708 in the mixed signal circuit design 700 were split into different analog and digital parts during the design aware partitioning, the digital partition 710 and the analog partition 720 can include new connectivity between the Verilog digital blocks 712 and 713 and the Verilog analog blocks 722 and 723.

Referring back to FIGS. 3 and 4, the adaptive partitioning system 310 can include a translation cell insertion unit 316 to insert translator cells at boundaries between the analog and digital partitions of the mixed-signal circuit design 301, which can allow the digital partition simulated by the digital simulator 332 to communicate with the analog partition simulated by the analog simulator 334.

The design verification tool 300 can include an elaboration system 320 to elaborate the translator cells, the analog partition, and the digital partition of the mixed-signal circuit design 301. The elaboration process can render the digital partition of the mixed-signal circuit design 301 possibly along with one or more of the translator cells into a format capable of being simulated by the digital simulator 332. The elaboration process also can render the analog partition possibly along with one or more of the translator cells into a format capable of being simulated by the analog simulator 334. The elaboration system 320 also can elaborate the test bench 302 into a format usable in the mixed-signal simulation environment.

The design verification tool 300 can include a functional verification unit 330 to implement a mixed-signal verification environment, which can simulate the mixed-signal circuit design 301 and the test bench 302. The functional verification unit 330 can perform analog simulation on the analog partition of the mixed-signal circuit design 301 with the analog simulator 334 and perform digital simulation on the digital partition of the mixed-signal circuit design 301 with the digital simulator 332. The digital simulator 332 can simulate the functional operations performed by the digital partition of the mixed-signal circuit design 301 in response to test stimulus generated by the test bench 302, for example, using an event-based discrete time events processor. The analog simulator 334 can simulate the functional operations performed by the analog partition of the mixed-signal circuit design 301 in response to the test stimulus generated by the test bench 302, for example, using a continuous time matrix-based differential equation solvers.

The functional verification unit 330 can generate verification results 303, for example, including waveform data corresponding to the functional operation of the mixed-signal circuit design 301 in the mixed-signal verification environment. The design verification system 300 (or a tool external to the design verification tool 300) can perform a functional verification of the mixed-signal circuit design 301, for example, by comparing the waveform data with an expected output from the mixed-signal circuit design 301 in response the test stimulus generated by the test bench 302.

The system and apparatus described above may use dedicated processor systems, micro controllers, programmable logic devices, microprocessors, or any combination thereof, to perform some or all of the operations described herein. Some of the operations described above may be implemented in software and other operations may be implemented in hardware. Any of the operations, processes, and/or methods described herein may be performed by an apparatus, a device, and/or a system substantially similar to those as described herein and with reference to the illustrated figures.

The processing device may execute instructions or “code” stored in memory. The memory may store data as well. The processing device may include, but may not be limited to, an analog processor, a digital processor, a microprocessor, a multi-core processor, a processor array, a network processor, or the like. The processing device may be part of an integrated control system or system manager, or may be provided as a portable electronic device configured to interface with a networked system either locally or remotely via wireless transmission.

The processor memory may be integrated together with the processing device, for example RAM or FLASH memory disposed within an integrated circuit microprocessor or the like. In other examples, the memory may comprise an independent device, such as an external disk drive, a storage array, a portable FLASH key fob, or the like. The memory and processing device may be operatively coupled together, or in communication with each other, for example by an I/O port, a network connection, or the like, and the processing device may read a file stored on the memory. Associated memory may be “read only” by design (ROM) by virtue of permission settings, or not. Other examples of memory may include, but may not be limited to, WORM, EPROM, EEPROM, FLASH, or the like, which may be implemented in solid state semiconductor devices. Other memories may comprise moving parts, such as a known rotating disk drive. All such memories may be “machine-readable” and may be readable by a processing device.

Operating instructions or commands may be implemented or embodied in tangible forms of stored computer software (also known as “computer program” or “code”). Programs, or code, may be stored in a digital memory and may be read by the processing device. “Computer-readable storage medium” (or alternatively, “machine-readable storage medium”) may include all of the foregoing types of memory, as well as new technologies of the future, as long as the memory may be capable of storing digital information in the nature of a computer program or other data, at least temporarily, and as long at the stored information may be “read” by an appropriate processing device. The term “computer-readable” may not be limited to the historical usage of “computer” to imply a complete mainframe, mini-computer, desktop or even laptop computer. Rather, “computer-readable” may comprise storage medium that may be readable by a processor, a processing device, or any computing system. Such media may be any available media that may be locally and/or remotely accessible by a computer or a processor, and may include volatile and non-volatile media, and removable and non-removable media, or any combination thereof.

A program stored in a computer-readable storage medium may comprise a computer program product. For example, a storage medium may be used as a convenient means to store or transport a computer program. For the sake of convenience, the operations may be described as various interconnected or coupled functional blocks or diagrams. However, there may be cases where these functional blocks or diagrams may be equivalently aggregated into a single logic device, program or operation with unclear boundaries.

### Conclusion

While the application describes specific examples of carrying out embodiments of the invention, those skilled in the art will appreciate that there are numerous variations and permutations of the above described systems and techniques that fall within the spirit and scope of the invention as set forth in the appended claims. For example, while specific terminology has been employed above to refer to design processes, it should be appreciated that various examples of the invention may be implemented using any desired combination of electronic design automation processes.

One of skill in the art will also recognize that the concepts taught herein can be tailored to a particular application in many other ways. In particular, those skilled in the art will recognize that the illustrated examples are but one of many alternative implementations that will become apparent upon reading this disclosure.

Although the specification may refer to “an”, “one”, “another”, or “some” example(s) in several locations, this does not necessarily mean that each such reference is to the same example(s), or that the feature only applies to a single example.

1. A method comprising:
classifying, by the computing system, a mixed-signal circuit design describing an electronic device having analog circuitry and digital circuitry based on a design topology of the mixed-signal circuit design;
selectively partitioning, by the computing system, the mixed-signal circuit design into an analog partition and a digital partition based, at least in part, on the classification of the mixed-signal circuit design; and
simulating, by the computing system, the analog partition of the mixed-signal circuit design with an analog simulator and the digital partition of the mixed-signal circuit design with a digital simulator.

2. The method of claim 1, wherein classifying the mixed-signal circuit design further comprises:
identifying a top-level design block in a design hierarchy of the mixed-signal circuit design;
traversing a connectivity of the design hierarchy of the mixed-signal circuit design to identify lower-level design blocks in the mixed-signal circuit design; and
classifying the mixed-signal circuit design based, at least in part, on at least one of a design type of the top-level design block, design types of the lower-level design blocks, or a connectivity of design blocks in the mixed-signal circuit design.

3. The method of claim 1, wherein selectively partitioning the mixed-signal circuit design further comprises partitioning the mixed-signal circuit design at a design block level when the classification of the mixed-signal circuit design corresponds to an analog-on-top topology, a digital-on-top topology, or an analog mixed-signal topology.

4. The method of claim 3, further comprising locating, by the computing system, transitions between types of design blocks in the mixed-signal circuit design, wherein the partitioning of the mixed-signal circuit design at the design block level is based on the transitions between types of design blocks in the mixed-signal circuit design.

5. The method of claim 4, further comprising inserting, by the computing system, one or more boundary design blocks into the analog partition or the digital partition of the mixed-signal circuit design at the transitions between the types of the design blocks based, at least in part, on the classification of the mixed-signal circuit design.

6. The method of claim 1, wherein selectively partitioning the mixed-signal circuit design further comprises partitioning the mixed-signal circuit design by processing the signals in the mixed-signal circuit design when the classification of the mixed-signal circuit design corresponds to a complex design topology.

7. The method of claim 1, further comprising inserting, by the computing system, translator cells into the mixed-signal circuit design between the analog partition and the digital partition, wherein the analog simulator and the digital simulator communicate during the simulation via the translator cells.

8. A system comprising:
a memory system configured to store computer-executable instructions; and
a computing system, in response to execution of the computer-executable instructions, is configured to:
classify a mixed-signal circuit design describing an electronic device having analog circuitry and digital circuitry based on a design topology of the mixed-signal circuit design;
selectively partition the mixed-signal circuit design into an analog partition and a digital partition based, at least in part, on the classification of the mixed-signal circuit design; and
simulate the analog partition of the mixed-signal circuit design with an analog simulator and the digital partition of the mixed-signal circuit design with a digital simulator.

9. The system of claim 8, wherein the computing system, in response to execution of the computer-executable instructions, is further configured to classify the mixed-signal circuit design by:
identifying a top-level design block in a design hierarchy of the mixed-signal circuit design;
traversing a connectivity of the design hierarchy of the mixed-signal circuit design to identify lower-level design blocks in the mixed-signal circuit design; and
classifying the mixed-signal circuit design based, at least in part, on at least one of a design type of the top-level design block, design types of the lower-level design blocks, or a connectivity of design blocks in the mixed-signal circuit design.

10. The system of claim 8, wherein the computing system, in response to execution of the computer-executable instructions, is further configured to selectively partition the mixed-signal circuit design by partitioning the mixed-signal circuit design at a design block level when the classification of the mixed-signal circuit design corresponds to an analog-on-top topology, a digital-on-top topology, or an analog mixed-signal topology.

11. The system of claim 10, wherein the computing system, in response to execution of the computer-executable instructions, is further configured to locate transitions between types of design blocks in the mixed-signal circuit design, and partition the mixed-signal circuit design at the design block level based on the transitions between types of design blocks in the mixed-signal circuit design.

12. The system of claim 11, wherein the computing system, in response to execution of the computer-executable instructions, is further configured to insert one or more boundary design blocks into the analog partition or the digital partition of the mixed-signal circuit design at the transitions between the types of the design blocks based, at least in part, on the classification of the mixed-signal circuit design.

13. The system of claim 8, wherein the computing system, in response to execution of the computer-executable instructions, is further configured to selectively partitioning the mixed-signal circuit design by partitioning the mixed-signal circuit design by processing the signals in the mixed-signal circuit design when the classification of the mixed-signal circuit design corresponds to a complex design topology.

14. An apparatus comprising at least one computer-readable memory device storing instructions configured to cause one or more processing devices in a computing system to perform operations comprising:
classifying a mixed-signal circuit design describing an electronic device having analog circuitry and digital circuitry based on a design topology of the mixed-signal circuit design;
selectively partitioning the mixed-signal circuit design into an analog partition and a digital partition based, at least in part, on the classification of the mixed-signal circuit design; and
simulating the analog partition of the mixed-signal circuit design with an analog simulator and the digital partition of the mixed-signal circuit design with a digital simulator.

15. The apparatus of claim 14, wherein classifying the mixed-signal circuit design further comprises:
identifying a top-level design block in a design hierarchy of the mixed-signal circuit design;
traversing a connectivity of the design hierarchy of the mixed-signal circuit design to identify lower-level design blocks in the mixed-signal circuit design; and
classifying the mixed-signal circuit design based, at least in part, on at least one of a design type of the top-level design block, design types of the lower-level design blocks, or a connectivity of design blocks in the mixed-signal circuit design.

16. The apparatus of claim 14, wherein selectively partitioning the mixed-signal circuit design further comprises partitioning the mixed-signal circuit design at a design block level when the classification of the mixed-signal circuit design corresponds to an analog-on-top topology, a digital-on-top topology, or an analog mixed-signal topology.

17. The apparatus of claim 16, wherein the instructions are configured to cause one or more processing devices to perform operations further comprising locating transitions between types of design blocks in the mixed-signal circuit design, wherein the partitioning of the mixed-signal circuit design at the design block level is based on the transitions between types of design blocks in the mixed-signal circuit design.

18. The apparatus of claim 17, wherein the instructions are configured to cause one or more processing devices to perform operations further comprising inserting one or more boundary design blocks into the analog partition or the digital partition of the mixed-signal circuit design at the transitions between the types of the design blocks based, at least in part, on the classification of the mixed-signal circuit design.

19. The apparatus of claim 14, wherein selectively partitioning the mixed-signal circuit design further comprises partitioning the mixed-signal circuit design by processing the signals in the mixed-signal circuit design when the classification of the mixed-signal circuit design corresponds to a complex design topology.

20. The apparatus of claim 14, wherein the instructions are configured to cause one or more processing devices to perform operations further comprising inserting translator cells into the mixed-signal circuit design between the analog partition and the digital partition, wherein the analog simulator and the digital simulator communicate during the simulation via the translator cells.
